(19) United States
(12) Patent Application Publication
(10) Pub. No.: US 2012/0239325 A1
(43) Pub. Date: Sep. 20, 2012

(54) BATTERY CAPACITY ESTIMATION

(75) Inventors: Imre Sunyi, Helsingborg (SE); Igor Gurovski, Malmo (SE)

(73) Assignee: SONY MOBILE COMMUNICATIONS AB, Lund (SE)

(21) Appl. No.: 13/391,839

(22) PCT Filed: Mar. 17, 2011
(86) PCT No.: PCT/IB2011/051128

§ 371 Date: Mar. 29, 2012

(51) Int. Cl. G01R 31/36; G06F 19/00

(52) U.S. Cl. 702/63

(57) ABSTRACT

A method comprising obtaining a voltage sample of a battery; converting the voltage sample to a battery capacity; calculating an average battery capacity based on averaging battery capacity values stored in a buffer; converting the average battery capacity to a voltage; calculating a current consumption based on the voltage sample and the voltage, wherein the current consumption corresponds to current consumed during a sampling period of the voltage sample; calculating a voting factor based on the current consumption; calculating a battery capacity difference based on a difference between the average battery capacity and the battery capacity; determining whether the battery capacity difference is greater than zero; and storing the average battery capacity in the buffer, a number of times, corresponding to the voting factor, when the battery capacity difference is equal to or less than zero.

### BACKGROUND

User devices, such as mobile and handheld devices, obtain power to operate based on a battery. Given the limited power supply that a battery offers, various approaches have been developed to estimate the capacity of the battery. A typical approach for estimating the battery capacity is to average the battery voltage readings. However, if the estimate of battery capacity is based on a small number of voltage samples, the estimate can change drastically over time. On the other hand, even when the estimate of battery capacity is based on a large number of voltage samples, the estimate can be inaccurate when the user device is consuming a substantial amount of current or when the battery is being charged.

### SUMMARY

According to one aspect, a method may comprise obtaining a voltage sample of a battery; converting the voltage sample to a battery capacity; calculating an average battery capacity based on averaging battery capacity values stored in a buffer; converting the average battery capacity to a voltage; calculating a current consumption based on the voltage sample and the voltage; calculating a voting factor based on the current consumption; calculating a battery capacity difference based on a difference between the average battery capacity and the battery capacity; determining whether the battery capacity difference is greater than zero; and storing the average battery capacity in the buffer, a number of times, corresponding to the voting factor, when the battery capacity difference is equal to or less than zero.

Additionally, the method may further comprise storing a reference current value, and wherein the calculating the voting factor may comprise calculating the voting factor based on a ratio between the current consumption and the reference current value.

Additionally, the method may further comprise storing a resistance value, and wherein the calculating the current consumption may comprise calculating the current consumption based on a difference between the voltage sample and the voltage divided by the resistance value.

Additionally, the method may further comprise storing a battery resolution value that indicates a minimum, reportable change of battery capacity, calculating a battery capacity value based on a difference between the average battery capacity and the battery resolution value; and storing the battery capacity value in the buffer, a number of times, corresponding to the voting factor, when the battery capacity difference is greater than zero.

Additionally, the method may further comprise calculating a buffer size based on a battery capacity value corresponding to when the battery is fully charged.

Additionally, the method may further comprise resetting a value of the voting factor when the calculated voting factor has a value of zero.

According to another aspect, a tangible computer-readable medium may comprise instructions for obtaining a voltage sample of a battery; converting the voltage sample to a battery capacity; calculating an average battery capacity based on averaging battery capacity values stored in a buffer; converting the average battery capacity to a voltage; calculating a current consumption based on the voltage sample and the voltage, wherein the current consumption corresponds to current consumed during a sampling period of the voltage sample; calculating a voting factor based on the current consumption; calculating a battery capacity difference based on a difference between the average battery capacity and the battery capacity; determining whether the battery capacity difference is greater than zero; and storing the average battery capacity in the buffer, a number of times, corresponding to the voting factor, in response to determining that the battery capacity difference is equal to or less than zero.

Additionally, the tangible computer-readable medium may comprise instructions for storing a reference current value, and wherein the instructions for calculating the voting factor may further comprise instructions for calculating the voting factor based on a ratio between the current consumption and the reference current value.

Additionally, the tangible computer-readable medium may comprise instructions for storing a resistance value, and wherein the instructions for calculating the current consumption may comprise instructions for calculating the current consumption based on a difference between the voltage sample and the voltage divided by the resistance value.

Additionally, the tangible computer-readable medium may comprise instructions for storing a battery resolution value that indicates a minimum, reportable change of battery capacity; calculating a battery capacity value based on a difference between the average battery capacity and the battery resolution value; and storing the battery capacity value in the buffer, a number of times, corresponding to the voting factor, when the battery capacity difference is greater than zero.

Additionally, the tangible computer-readable medium may comprise instructions for resetting a value of the voting factor when the calculated voting factor has a value of zero.

According to yet another aspect, a user device may comprise a battery, a buffer, a memory to store instructions, and a processing system to execute the instructions that configure the processing system to obtain a voltage sample of the battery; convert the voltage sample to a battery capacity; calculate an average battery capacity based on averaging battery capacity values stored in the buffer; convert the average battery capacity to a voltage; calculate a current consumption based on the voltage sample and the voltage, wherein the current consumption corresponds to current consumed during a sampling period of the voltage sample; calculate a voting factor based on the current consumption; calculate a battery capacity difference based on a difference between the average battery capacity and the battery capacity; determine whether the battery capacity difference is greater than zero; and store the average battery capacity in the buffer, a number of times, corresponding to the voting factor, when the battery capacity difference is equal to or less than zero.

Additionally, the user device may be further configured to store a reference current value, and wherein when calculating the voting factor, the user device may be further configured to calculate the voting factor based on a ratio between the current consumption and the reference current value.

Additionally, the user device may be further configured to store a resistance value, and wherein when calculating the current consumption, the user device may be further configured to calculate the current consumption based on a difference between the voltage sample and the voltage divided by the resistance value.

Additionally, the user device may be further configured to store a battery resolution value that indicates a minimum, reportable change of battery capacity, calculate a battery capacity value based on a difference between the average battery capacity and the battery resolution value, and store the battery capacity value in the buffer, a number of times, the number of times corresponding to the voting factor, when the battery capacity difference is greater than zero.

Additionally, the user device may be further configured to reset a value of the voting factor when the calculated voting factor has a value of zero.

Additionally, the user device may be further configured to periodically obtain a voltage sample of the battery.

Additionally, the user device, when calculating the voting factor, may be further configured to round a voting factor value to a nearest integer value.

Additionally, the buffer may have a buffer size based on a value equal to twice a battery capacity of the battery when the battery is fully charged.

Additionally, the user device may comprise a mobile communication device.

### BRIEF DESCRIPTION OF THE DRAWINGS

The accompanying drawings, which are incorporated in and constitute a part of this specification, illustrate exemplary embodiments described herein and, together with the description, explain these exemplary embodiments. In the drawings:

FIG. 1 is a diagram illustrating a buffer that stores battery capacity values according to an exemplary embodiment of a battery capacity estimation (BCE) algorithm;

FIG. 2 is a diagram illustrating an exemplary user device;

FIG. 3 is a diagram illustrating exemplary components of the user device depicted in FIG. 2; and

FIGS. 4A and 4B are flow diagrams illustrating an exemplary process pertaining to battery capacity estimation.

### DETAILED DESCRIPTION

The following detailed description refers to the accompanying drawings. The same reference numbers in different drawings may identify the same or similar elements. Also, the following description does not limit the invention. Rather, the scope of the invention is defined by the appended claims.

A problem with battery capacity estimation is that the battery voltage cannot be measured directly. For example, the battery, alone, has a particular voltage, and a voltage inside a user device that includes the battery, has another voltage. Since there is resistance inherent in the user device and internal resistance in the battery, this impacts the battery voltage reading due to voltage loss over the resistance. This voltage loss can impact the accuracy of an estimate of the battery capacity, the extent of which depends on where the battery voltage is on a discharge curve because typically, the discharge curve is not linear. For example, for a lithium cell of 4.2V, the discharge curve around 3.8 V is quite flat and a small change in current consumption will significantly impact a battery voltage reading and a corresponding battery capacity. By way of example, a battery voltage of 3.8 V will translate into a battery capacity of 45%. If current consumption increases to 1 amp, the voltage read at a measuring point can drop to 3.6 V, which will translate into a battery capacity of 3%.

As previously discussed, to compensate for voltage fluctuations, some kind of current measurement circuit is typically used. However, incorporating a current measurement circuit with a printed board assembly (PBA) can add cost, occupy space, and further add to current consumption when performing current measurements.

According to exemplary embodiments, a battery capacity estimation (BCE) algorithm is provided in which estimates of battery capacities are derived based on voltage readings and without current values obtained from a current measurement circuit.

According to an exemplary embodiment, the BCE algorithm may calculate an estimate of real current consumption based on an open circuit voltage, a sampling voltage, and a known resistance. The BCE algorithm may also calculate a voting factor based on a ratio between the estimate of the real current consumption and a nominal or reference current consumption value. The BCE algorithm may calculate a battery capacity difference value. The battery capacity difference value is a difference value between a battery capacity pertaining to a voltage sample reading and an average battery capacity of a buffer (e.g., a first-in-first-out (FIFO) buffer or some other suitable data structure) that stores battery capacity values.

The BCE algorithm may then determine whether the battery capacity difference value is greater or less than zero. If the battery capacity difference value is greater than zero, the BCE algorithm may store in the buffer the average battery capacity value decremented by a battery capacity resolution value (i.e., a minimum change in battery capacity that is capable of being reported) for the number of times equal to the voting factor. On the other hand, if the battery capacity difference value is less than zero, the BCE algorithm may store in the buffer the average battery capacity value for the number of times equal to the voting factor. According to such an implementation, a time factor, which is represented by the number of samples in the buffer, may be changed, and more accurate battery estimations relative to existing techniques may be calculated.

Described below is an example of the BCE algorithm. A battery has a particular rated battery capacity, which is a measure of the charge stored by the battery. Battery capacity may be defined in terms of current/per time unit. In this description, battery capacity is denoted by C (milliamp hour (mAh)). A nominal or reference current consumption is denoted by I_n (mA).

According to exemplary embodiments, the voltage of the battery is sampled and the sampling time interval is denoted by S_i (seconds). The voltage sample of the battery may be denoted by V_bat (volts). Since a path between the battery and a measuring point for obtaining the voltage sample includes resistance (e.g., inner battery resistance, connector resistance, trace resistance, etc.), such resistance is denoted by R_s (ohms) A sampling or usage time period is denoted by T_u (hour).

As an example, assume that a battery of a user device has the following exemplary parameters:

C=1000 mAh

I_n=100 mA

S_i=10 seconds

T_u=0.1 hour=6 minutes=360 seconds

R_s=0.2 ohms.

Based on the values indicated above, a user device that consumes I_n (mA) for T_u (h), will consume:

100 mA*0.1 h=10 mAh,

which is 1% of the rated battery capacity C

$$( i . e . , \frac{10 mAh}{1000 mAh} = 1 \% ) .$$

Given that the sampling interval S_i=10 seconds and T_u=360 seconds, a total of 36 samples of voltage is obtained, in which each V_bat value (i.e., voltage sample) may be translated into a battery capacity based on a look-up table (LUT) that maps voltage to battery capacity. The translated V_bat to a battery capacity is denoted by C_vbat. According to this example, a battery capacity resolution is denoted by Res_bat=1%. In other words, the buffer that stores 36 samples will be completely filled with battery capacity values before a reported battery capacity is changed 1% from a previously reported value (e.g., a reported, minimum change in battery capacity relative to a previously reported battery capacity is 1%).

Based on the framework above, the accuracy of battery capacity can be compromised. For example, assume that the buffer stores a battery capacity average of 50% (e.g., 36 samples each indicate a battery capacity of 50%). Subsequently, 10 V_bat samples are obtained which, after LUT translation, indicate a battery capacity of 43%. Thus, in this example, after 1 minute of nominal current consumption (e.g., 100 mA), if the samples are averaged with the other 36 samples, the reportable battery capacity would be approximately 48%. However, 48% would not be accurate because a nominal current of 100 mA for 6 minutes corresponds to a 1% change in capacity.

According to an exemplary embodiment, a buffer size of the buffer may be based on the following expression:

Buffer_size=(2*C*Res_bat*T_{—}u)/(I_{—}n*S_{—}i).

Given the exemplary values previously mentioned, the buffer size will have a value of:

Buffer_size=(2*1000*0.01*3600)/(100*10)=72.

According to an exemplary embodiment, the BCE algorithm may calculate an open circuit voltage denoted by OCV (volts) of the battery. According to such an embodiment, the OCV may calculated by calculating the average battery capacity stored in the buffer, denoted by C_avg(mAh), and reverse translating the average to a voltage. Based on this assumption, an estimate of the voltage drop over R_s can be calculated and a current consumption during the battery voltage sampling reading can be obtained.

For example, the battery capacity samples in the buffer may be averaged to calculate C_avg. Using the LUT, C_avg can be reversed translated (e.g., using the LUT) to a voltage denoted by OCV. Based on the value of OCV, a real current consumption value can be calculated based on the following expression:

$$I\_r = \frac{\vert ( OCV - V\_bat ) \vert}{R\_s} .$$

The BCE algorithm may also calculate a voting factor F based on the following expression:

$$F = \frac{I\_r}{I\_n} .$$

As previously described, the voting factor F indicates the number of times a battery capacity value is stored in the buffer, as described further below.

As an example, it may be assumed that the user device has been in a standby mode for a period of time. It may be further assumed that the current consumption in the standby mode is negligible (e.g., ˜3 mA) and the voltage loss due to the inner resistance is also negligible. Based on these assumptions, the voltage samples V_bat read while the user device is in standby mode are approximately the same as the OCV.

Based on the above, it may be assumed that the battery capacity average in the buffer, denoted by C_a=50% (e.g., all 72 samples stored in the buffer average to a battery capacity of 50%). The OCV of a battery capacity of 50%=3.814 V. Subsequently, the user device begins to consume current and the next V_bat sampling reading is 3.794V, which reverse translates, via a LUT, to a 43% battery capacity.

According to the BCE algorithm, a real current consumption will be calculated:

$$I\_r = \frac{\vert ( OCV - V\_bat ) \vert}{R\_s} = \frac{3.814 - 3.794}{0.2} = 100 mA .$$

The voting factor F will also be calculated:

$$F = \frac{I\_r}{I\_n} = \frac{100 mA}{100 mA} = 1.$$

The BCE algorithm may then calculate a battery capacity difference C_diff based on the following expression:

C_diff=C_avg−C_vbat=50%−43%=7%

Since the value of C_diff is greater than zero, the BCE algorithm may select a battery capacity value to store in the buffer, based on the following expression:

(C_avg−Res_bat)F=(50−1)=49%,

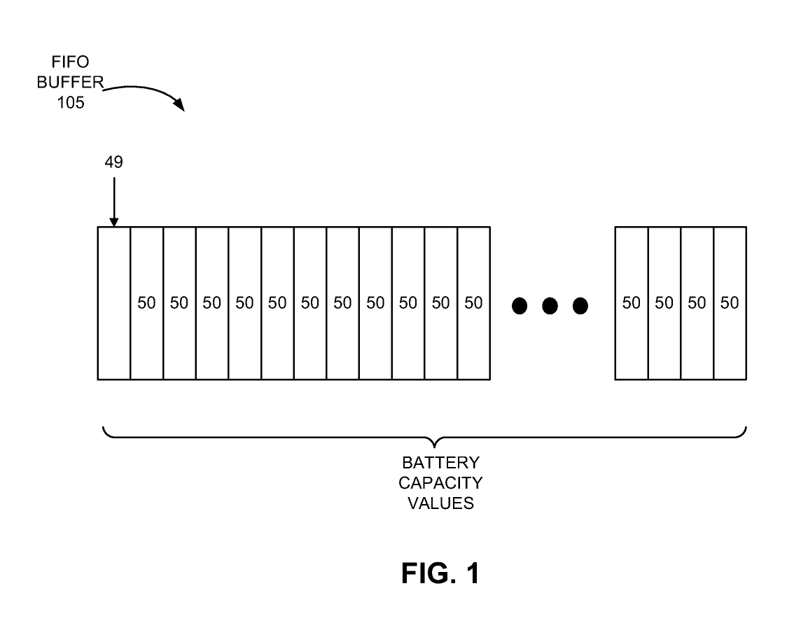

and since the voting factor F=1, the BCE algorithm may store the battery capacity of 49% only once in the buffer. That is, in view of the above values, according to the BCE algorithm, instead of storing a battery capacity value=43% in the buffer, the battery capacity value stored in the buffer (e.g., a FIFO buffer 105), as illustrated in FIG. 1, is 49%.

If the same current consumption continues when the next sampling interval transpires, again, the battery value would be equal to 43%, however, the BCE algorithm will store in the buffer the battery capacity value=49%. If again, the same current consumption continues for a total of 36 sample reads (i.e., 360 seconds), the average battery capacity in the buffer will change to:

((50*Buffer_size)/2+49*Buffer_size)/2)/Buffer_size=49%,

when rounded to the nearest integer.

If the same current consumption continues when the next sampling interval transpires, the BCE algorithm will store in the buffer the battery capacity value=48% (i.e., (C_avg−Res_bat)=(49−1)=48%). The OCV of a battery capacity of 48%=3.81 V. If the user device consumes less current (i.e., less than 100 mA), the voltage sample read could be 3.806 V, which corresponds to the 48%. In such a case, the voting factor F would be zero. However, if the voting factor F value equals zero, according to an exemplary embodiment, the BCE algorithm sets the voting factor F value equal to 1. Additionally, when C_diff equals zero or less than zero, according to an exemplary embodiment, the BCE algorithm stores a battery capacity equal to C_avg. In this case, the BCE algorithm would store the battery capacity value=48%.

If the current consumption increases, the V_bat sampling reading could be 3.73 V, which translates to a battery capacity=18%. Based on these values, the BCE algorithm would calculate the real current consumption:

$$I\_r = \frac{\vert ( OCV - V\_bat ) \vert}{R\_s} = \frac{3.814 - 3.730}{0.2} = 420 mA .$$

The voting factor F will also be calculated:

$$F = \frac{I\_r}{I\_n} = \frac{420 mA}{100 mA} = 4.$$

In view of the above values, according to the BCE algorithm, instead of putting a battery capacity value=18%, the battery capacity value stored in the buffer (e.g., buffer 105) will be calculated as:

(C_avg−Res_bat)=(48−1)=47%

Also, since the voting factor F=4, the BCE algorithm will store the battery capacity of 47% four times in the buffer (e.g., buffer 105).

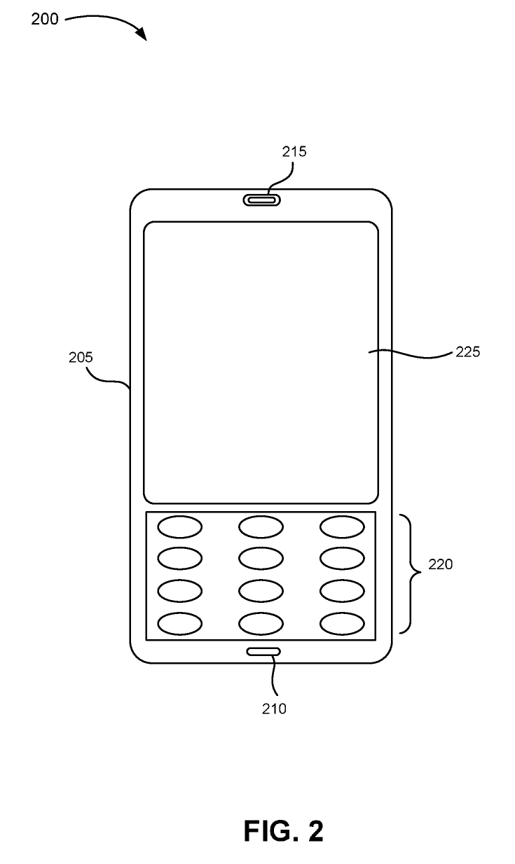

FIG. 2 is a diagram illustrating an exemplary user device 200 in which exemplary embodiments described herein may be implemented. The term “user device,” as used herein, is intended to be broadly interpreted to comprise a variety of devices. User device 200 may correspond to a portable device, a mobile device, a tablet device, a stationary device, or a handheld device. For example, user device 200 may take the form of a telephone (e.g., a smart phone, a radio phone, a cellular phone, a wireless phone, etc.), a personal digital assistant (PDA), a data organizer, a calculator, a picture capturing device, a video capturing device, a computer, a Web-access device, a music playing device, a location-aware device, a gaming device, a computer, some other type of user device, or an accessory to a user device (e.g., a headset, etc.).

As illustrated in FIG. 2, user device 200 may comprise a housing 205, a microphone 210, speakers 215, keys 220, and a display 225. According to other embodiments, user device 200 may comprise fewer components, additional components, different components, and/or a different arrangement of components than those illustrated in FIG. 2 and described herein. Additionally, or alternatively, although user device 200 is depicted as having a portrait configuration, according to other embodiments, user device 200 may have a landscape configuration or some other type of configuration (e.g., a clamshell configuration, a slider configuration, a candy bar configuration, a swivel configuration, etc.).

Housing 205 may comprise a structure to contain components of user device 200. For example, housing 205 may be formed from plastic, metal, or some other type of material. Housing 205 may structurally support microphone 210, speakers 215, keys 220, and display 225. Microphone 210 may transduce a sound wave to a corresponding electrical signal. For example, a user may speak into microphone 210 during a telephone call, to execute a voice command, to execute a voice-to-text conversion, etc. Speakers 215 may transduce an electrical signal to a corresponding sound wave. For example, a user may listen to music, to a calling party, etc., through speakers 215.

Keys 220 may provide input to user device 200. For example, keys 220 may comprise a standard telephone keypad, a QWERTY keypad, and/or some other type of keypad (e.g., a calculator keypad, a numerical keypad, etc.). Keys 220 may also comprise special purpose keys to provide a particular function (e.g., send a message, place a call, open an application, etc.) and/or allow a user to select and/or navigate through user interfaces or other content displayed by display 225.

Display 225 may operate as an output component. For example, display 225 may comprise a liquid crystal display (LCD), a plasma display panel (PDP), a field emission display (FED) a thin film transistor (TFT) display, or some other type of display technology. Additionally, according to an exemplary implementation, display 225 may operate as an input component. For example, display 225 may comprise a touch-sensitive screen. In such instances, display 225 may correspond to a single-point input device (e.g., capable of sensing a single touch) or a multipoint input device (e.g., capable of sensing multiple touches that occur at the same time). Display 225 may be implemented using one of a variety of sensing technologies, such as, for example, capacitive sensing, surface acoustic wave sensing, resistive sensing, optical sensing, pressure sensing, infrared sensing, or gesture sensing. Display 225 may also provide for an auto-rotating function (e.g., automatically rotate images displayed on display 225 based on the orientation of display 225), as well as be responsive to other user-touch gestures (e.g., zoom, expand, etc.). Display 225 may be capable of displaying text, pictures, and video. Display 225 may also be capable of displaying various images (e.g., icons, objects, etc.) that may be selected by a user to access various applications, enter data, navigate through user interfaces, etc.

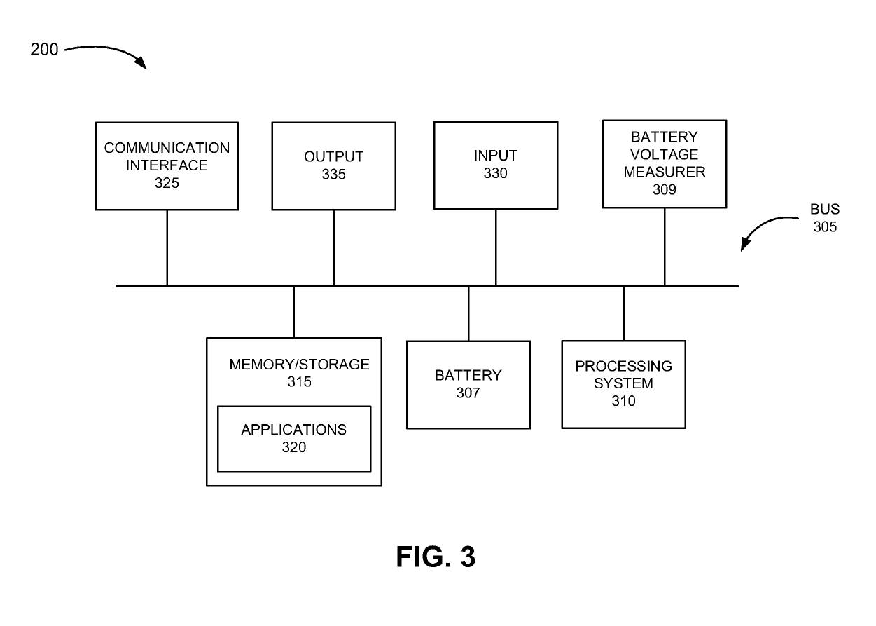

FIG. 3 is a diagram illustrating exemplary components of user device 200. As illustrated, user device 200 may comprise a bus 305, a battery 307, a battery voltage measurer 309, a processing system 310, a memory/storage 315 that may comprise applications 320, a communication interface 325, an input 330, and an output 335. According to other embodiments, user device 200 may comprise fewer components, additional components, different components, and/or a different arrangement of components than those illustrated in FIG. 3 and described herein.

Bus 305 may comprise a path that permits communication among the components of user device 200. For example, bus 305 may include a system bus, an address bus, a data bus, and/or a control bus. Bus 305 may also include bus drivers, bus arbiters, bus interfaces, and/or clocks.

Battery 307 may correspond to a battery, a cell, or some other power source. By way of example, battery 307 may take the form of a lithium ion battery, a battery pack, a lithium-polymer battery, or some other type of voltage supply. Battery voltage measurer 309 may include a circuit that measures (e.g., periodically) the voltage of battery 307. Battery voltage measurer 309 may include an analog-to-digital converter.

Processing system 310 may include one or multiple processors, microprocessors, data processors, co-processors, application specific integrated circuits (ASICs), system-on-chips (SOCs), application specific instruction-set processors (ASIPs), controllers, programmable logic devices (PLDs), chipsets, field programmable gate arrays (FPGAs), and/or some other processing logic that may interpret and/or execute instructions and/or data. Processing system 310 may control the overall operation, or a portion of operation(s) performed by user device 200. Processing system 310 may perform operations based on an operating system and/or various applications (e.g., applications 320). Processing system 310 may access instructions from memory/storage 315, from other components of user device 200, and/or from a source external to user device 200 (e.g., another device or a network).

Memory/storage 315 may comprise one or multiple memories and/or one or multiple other types of tangible storage mediums. For example, memory/storage 315 may comprise one or more types of memories, such as, a random access memory (RAM), a dynamic random access memory (DRAM), a cache, a static random access memory (SRAM), a read only memory (ROM), a programmable read only memory (PROM), a ferroelectric random access memory (FRAM), an erasable programmable read only memory (EPROM), s static random access memory (SRAM), a flash memory, and/or some other form of storing hardware. Memory/storage 315 may comprise a hard disk (e.g., a magnetic disk, an optical disk, a magneto-optic disk, a solid state disk, etc.) and a corresponding drive. Memory/storage 315 may be external to and/or removable from user device 200, such as, for example, a Universal Serial Bus (USB) memory, a dongle, a hard disk, mass storage, off-line storage, or some other type of storing medium (e.g., a computer-readable medium, a compact disk (CD), a digital versatile disk (DVD), a Blu-ray™ disc (BD), or the like). The term “computer-readable medium,” as used herein, is intended to be broadly interpreted to comprise, for example, a memory, a CD, a DVD, a BD, or another type of tangible storage medium.

Memory/storage 315 may store data, applications 320, and/or instructions related to the operation of user device 200. Applications 320 may comprise software that provides various services or functions. By way of example, applications 320 may comprise a telephone application, a voice recognition application, a video application, a multi-media application, a music playing application, a texting application, an instant messaging application, etc. Additionally, according to an exemplary embodiment, applications 320 may include an application that corresponds to the BCE algorithm described herein.

Communication interface 325 may permit user device 200 to communicate with other devices, networks, and/or systems. For example, communication interface 325 may comprise one or multiple wireless and/or wired communication interfaces. Communication interface 325 may comprise a transmitter and a receiver, or a transceiver. Communication interface 325 may operate according to one or multiple protocols, communication standards, or the like.

Input 330 may permit an input into user device 200. For example, input 330 may comprise a keyboard, a keypad (e.g., keypad 220), a touch screen (e.g., display 225), a touch pad, a mouse, a port, a button, a switch, a microphone (e.g., microphone 210), voice recognition logic, an input port, a knob, and/or some other type of input component (e.g., a light sensor). Output 335 may permit user device 200 to provide an output. For example, output 335 may include a display (e.g., display 225), a speaker (e.g., speakers 215), an LED, an output port, a vibratory mechanism, or some other type of output component.

User device 200 may perform operations in response to processing system 310 executing software instructions stored by memory/storage 315. For example, the software instructions may be read into memory/storage 315 from another storing medium or from another device via communication interface 325. The software instructions stored by memory/storage 315 may cause processing system 310 to perform various processes. Alternatively, user device 200 may perform processes based on the execution of hardware, hardware and firmware, and/or hardware, software, and firmware.

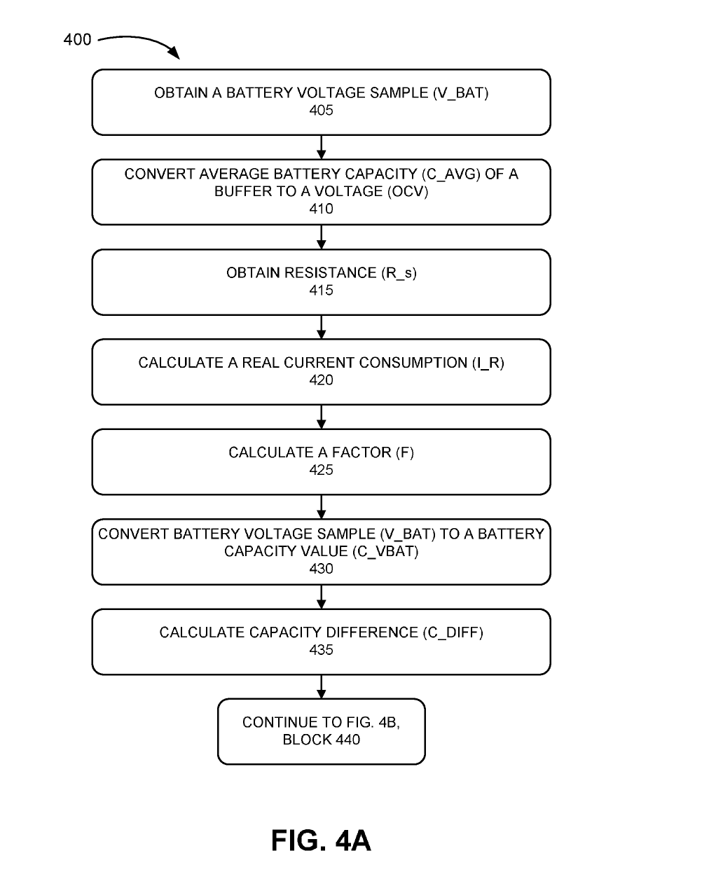

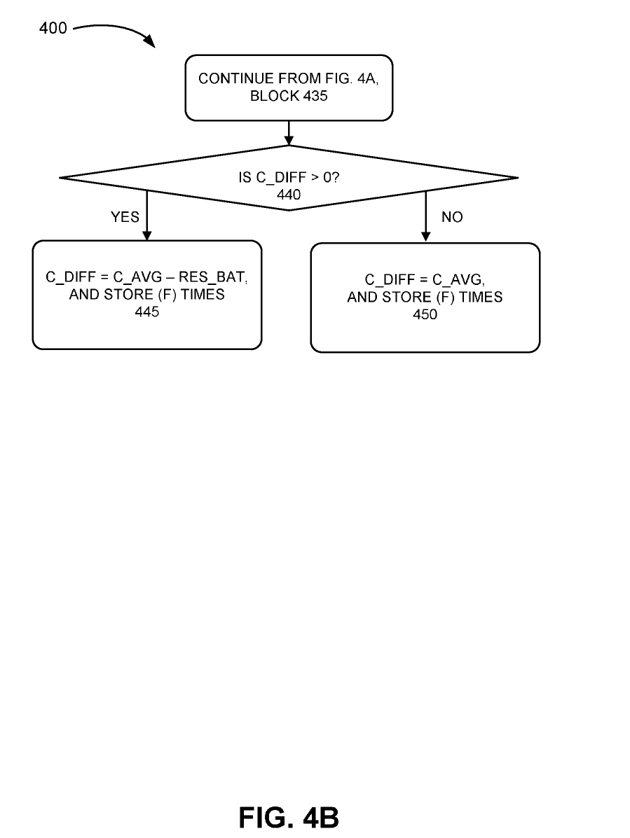

FIGS. 4A and 4B are flow diagrams illustrating an exemplary process 400 pertaining to battery capacity estimation. According to an exemplary implementation, process 400 may be performed by user device 200. For example, processing system 310 may execute an application 320 (e.g., a BCE program stored in memory/storage 315) in conjunction with battery voltage measurer 309.

Referring to FIG. 4A, process 400 includes obtaining a battery voltage sample (block 405). For example, battery voltage measurer 309 may obtain a voltage sample V_bat of battery 307 according to a sampling time interval S_i. Battery voltage measurer 309 may provide the voltage sample V_bat to processing system 310 that is executing application 320 (e.g., the BCE application).

An average battery capacity of a buffer is converted to a voltage (block 410). For example, a buffer (e.g., buffer 105) stores battery capacity values. Processing system 310 and application 320 calculate an average of the stored battery capacity values and a reverse translation, via an LUT, of the average battery capacity C_avg to a voltage OCV is calculated.

A known resistance is obtained (block 415). For example, a path between the battery (e.g., battery 307) and a measuring point for obtaining the voltage sample V_bat includes a known resistance R_s. Processing system 310 and application 320 may use a pre-stored resistance R_s in memory/storage 315 for calculating the real current consumption described in block 420.

A real current consumption is calculated (block 420). For example, processing system 310 and application 320 may calculate a real current consumption based on the following expression:

$$I\_r = \frac{\vert ( OCV - V\_bat ) \vert}{R\_s} .$$

A voting factor is calculated (block 425). For example, processing system 310 and application 320 may calculate the voting factor is based on the real current consumption value I_r and a nominal or reference current I_n (e.g., which may be a pre-stored value stored in memory/storage 320) based on the following expression:

$$F = \frac{I\_r}{I\_n} .$$

According to an exemplary embodiment, in the event the voting factor F has a value of zero, the voting factor F is assigned a value of 1. Otherwise, the voting factor F is rounded to the nearest integer value.

The battery voltage sample is converted to a battery capacity (block 430). For example, processing system 310 and application 320 may convert the voltage sample V_bat to a battery capacity value C_vbat based on an LUT.

A capacity difference is calculated (block 435). For example, processing system 310 and application 320 may calculate a capacity difference C_diff based on the average battery capacity C_avg and the battery capacity value C_vbat according to the following expression:

C_diff=C_avg−C_vbat.

Referring to FIG. 4B, it is determined whether the capacity difference is greater than zero (block 440). For example, processing system 310 and application 320 determines whether the capacity difference is greater than zero. If it is determined that the capacity difference is greater than zero (block 440-YES), the average battery capacity C_avg is decremented by the battery capacity resolution Res_bat and stored in the buffer F times (block 445). For example, processing system 310 and application 320 decrements the average battery capacity C_avg by the battery capacity resolution Res_bat and stores that value in buffer 105 F times. However, if it is determined that the capacity difference is less than or equal to zero (block 440-NO), the average battery capacity C_avg is stored in the buffer F times (block 450). For example, processing system 310 and application 320 stores the average battery capacity C_avg in buffer 105 F times.

Although FIGS. 4A and 4B illustrate an exemplary process 400, in other implementations, process 400 may include additional operations, fewer operations, and/or different operations than those illustrated and described with respect to FIGS. 4A and 4B.

As a result of the foregoing, the BCE algorithm described may improve the accuracy of battery capacity estimation. In turn, the operation of the user device may be significantly improved. For example, the user device may not shut-off prematurely when the user device has a more accurate estimation of battery capacity. According to another example, the user device may fully charge its battery based on a more accurate estimation of battery capacity. The BCE algorithm described may provide other advantages, not specifically mentioned, that naturally flow from calculating an accurate estimation of battery capacity.

The foregoing description of embodiments provides illustration, but is not intended to be exhaustive or to limit implementations to the precise form disclosed. Modifications and variations of the embodiments and/or implementations are possible in light of the above teachings, or may be acquired from practice of the teachings. For example, the values described in this description are exemplary and other values corresponding to the specifics of a user device may be implemented based on this description. While not exhaustive, such values pertain to usage period time, sampling time, resistance, battery capacity resolution, etc.

The flowchart and blocks illustrated and described with respect to FIGS. 4A and 4B illustrate an exemplary process according to an exemplary embodiment. However, according to other embodiments, the function(s) or act(s) described with respect to a block or block(s) may be performed in an order that is different than the order illustrated and described. For example, two or more blocks may be performed concurrently, substantially concurrently, or in reverse order, depending on, among other things, dependency of a block to another block.

Embodiments may take the form of an entirely software embodiment (e.g., including firmware, resident software, micro-code, etc.). Alternatively, embodiments may take the form of a combination of software and hardware (e.g., a circuit, a module, a system, etc.). Furthermore, embodiments may take the form of a computer program product embodied on a tangible computer-readable medium.

The terms “comprise,” “comprises” or “comprising,” as well as synonyms thereof (e.g., include, etc.), when used in the specification is meant to specify the presence of stated features, integers, steps, or components but does not preclude the presence or addition of one or more other features, integers, steps, components, or groups thereof. In other words, these terms are to be interpreted as inclusion without limitation.

The terms “a,” “an,” and “the” are intended to be interpreted to include both the singular and plural forms, unless the context clearly indicates otherwise. Further, the phrase “based on” is intended to be interpreted to mean, for example, “based, at least in part, on,” unless explicitly stated otherwise. The term “and/or” is intended to be interpreted to include any and all combinations of one or more of the associated list items.

No element, act, or instruction disclosed in the specification should be construed as critical or essential to the embodiments described herein unless explicitly described as such.

What is claimed is:

1. A method comprising:
obtaining a voltage sample of a battery;
converting the voltage sample to a battery capacity;
calculating an average battery capacity based on averaging battery capacity values stored in a buffer;
converting the average battery capacity to a voltage;
calculating a current consumption based on the voltage sample and the voltage;
calculating a voting factor based on the current consumption;
calculating a battery capacity difference based on a difference between the average battery capacity and the battery capacity;
determining whether the battery capacity difference is greater than zero; and
storing the average battery capacity in the buffer, a number of times, corresponding to the voting factor, when the battery capacity difference is equal to or less than zero.

2. The method of claim 1, further comprising:
storing a reference current value, and wherein the calculating the voting factor further comprises:
calculating the voting factor based on a ratio between the current consumption and the reference current value.

3. The method of claim 1, further comprising:
storing a resistance value, and wherein the calculating the current consumption comprises:
calculating the current consumption based on a difference between the voltage sample and the voltage divided by the resistance value.

4. The method of claim 1, further comprising:
storing a battery resolution value that indicates a minimum, reportable change of battery capacity;
calculating a battery capacity value based on a difference between the average battery capacity and the battery resolution value; and
storing the battery capacity value in the buffer, a number of times, corresponding to the voting factor, when the battery capacity difference is greater than zero.

5. The method of claim 1, further comprising:
calculating a buffer size based on a battery capacity value corresponding to when the battery is fully charged.

6. The method of claim 1, further comprising:
resetting a value of the voting factor when the calculated voting factor has a value of zero.

7. A tangible computer-readable medium comprising instructions for:
obtaining a voltage sample of a battery;
converting the voltage sample to a battery capacity;
calculating an average battery capacity based on averaging battery capacity values stored in a buffer;
converting the average battery capacity to a voltage;
calculating a current consumption based on the voltage sample and the voltage, wherein the current consumption corresponds to current consumed during a sampling period of the voltage sample;
calculating a voting factor based on the current consumption;
calculating a battery capacity difference based on a difference between the average battery capacity and the battery capacity;
determining whether the battery capacity difference is greater than zero; and
storing the average battery capacity in the buffer, a number of times, corresponding to the voting factor, in response to determining that the battery capacity difference is equal to or less than zero.

8. The tangible computer-readable medium of claim 7, further comprising instructions for:
storing a reference current value, and wherein the instructions for calculating the voting factor further comprise instructions for:
calculating the voting factor based on a ratio between the current consumption and the reference current value.

9. The tangible computer-readable medium of claim 7, further comprising instructions for:
storing a resistance value, and wherein the instructions for calculating the current consumption comprise instructions for:
calculating the current consumption based on a difference between the voltage sample and the voltage divided by the resistance value.

10. The tangible computer-readable medium of claim 7, further comprising instructions for:
storing a battery resolution value that indicates a minimum, reportable change of battery capacity;
calculating a battery capacity value based on a difference between the average battery capacity and the battery resolution value; and
storing the battery capacity value in the buffer, a number of times, corresponding to the voting factor, when the battery capacity difference is greater than zero.

11. The tangible computer-readable medium of claim 7, further comprising instructions for:
resetting a value of the voting factor when the calculated voting factor has a value of zero.

12. A user device comprising:
a battery;
a buffer;
a memory to store instructions; and
a processing system to execute the instructions that configure the processing system to:
obtain a voltage sample of the battery;
convert the voltage sample to a battery capacity;
calculate an average battery capacity based on averaging battery capacity values stored in the buffer; convert the average battery capacity to a voltage;
calculate a current consumption based on the voltage sample and the voltage, wherein the current consumption corresponds to current consumed during a sampling period of the voltage sample;
calculate a voting factor based on the current consumption;
calculate a battery capacity difference based on a difference between the average battery capacity and the battery capacity;
determine whether the battery capacity difference is greater than zero; and
store the average battery capacity in the buffer, a number of times, corresponding to the voting factor, when the battery capacity difference is equal to or less than zero.

13. The user device of claim 12, wherein the processing system is further configured to:
store a reference current value, and wherein when calculating the voting factor, the processing system is further configured to:
calculate the voting factor based on a ratio between the current consumption and the reference current value.

14. The user device of claim 12, wherein the processing system is further configured to:
store a resistance value, and wherein when calculating the current consumption, the processing system is further configured to:
calculate the current consumption based on a difference between the voltage sample and the voltage divided by the resistance value.

15. The user device of claim 12, wherein the processing system is further configured to:
store a battery resolution value that indicates a minimum, reportable change of battery capacity;
calculate a battery capacity value based on a difference between the average battery capacity and the battery resolution value; and
store the battery capacity value in the buffer, a number of times, the number of times corresponding to the voting factor, when the battery capacity difference is greater than zero.

16. The user device of claim 12, wherein the processing system is further configured to:
reset a value of the voting factor when the calculated voting factor has a value of zero.

17. The user device of claim 12, wherein the processing system is further configured to:
periodically obtain a voltage sample of the battery.

18. The user device of claim 12, wherein when calculating the voting factor, the processing system is further configured to:
round a voting factor value to a nearest integer value.

19. The user device of claim 12, wherein the buffer has a buffer size based on a value equal to twice a battery capacity of the battery when the battery is fully charged.

20. The user device of claim 12, wherein the user device comprises a mobile communication device.
